(19) United States
(12) Patent Application Publication
(10) Pub. No.: US 2013/0021757 A1
(43) Pub. Date: Jan. 24, 2013

(54) PORTABLE ELECTRONIC SYSTEM

(71) Applicants: Wei-Hsin SHIH, Iaipei (TW); Kuei-Shun Yeh, Taipei (TW); Chung-Yuan Kuang, Taipei (TW)

(72) Inventors: Wei-Hsin SHIH, Iaipei (TW); Kuei-Shun Yeh, Taipei (TW); Chung-Yuan Kuang, Taipei (TW)

(21) Appl. No.: 13/554,439

(22) Filed: Jul. 20, 2012

Related U.S. Application Data
(60) Provisional application No. 61/510,208, filed on Jul. 21, 2011.

(51) Int. Cl. H05K 7/16; H05K 7/14

(52) U.S. Cl. 361/727; 361/679.01

(57) ABSTRACT

A portable electronic system includes a first electronic device, a carrying element and a second electronic device. The first electronic device has a casing. The casing has an accommodating portion located at one side of the casing. The carrying element is connected with the casing and capable of relatively moving between a first position and a second position of the casing. The second electronic device is disposed at the carrying element and coupled to the first electronic device. When the carrying element is located at the first position, the second electronic device is received within the accommodating portion by the carrying element. When the carrying element is located at the second position, the second electronic device is departed from the accommodating portion by the carrying element.

### CROSS REFERENCE TO RELATED APPLICATIONS

The non-provisional patent application claims priority to U.S. provisional patent application with Ser. No. 61/510,208 filed on Jul. 21, 2011. This and all other extrinsic materials discussed herein are incorporated by reference in their entirety.

### BACKGROUND OF THE INVENTION

1. Field of Invention

The disclosure relates to a portable electronic system and, in particular, to a detachable portable electronic system.

2. Related Art

As the progressive of information technology, the requirements of real-time and convenient information search as well as the communication quality are dramatically grown. Various kinds of consuming electronic products are continuously developed for providing more convenient life and satisfying our needs. The electronic products, such as mobile phones, tablet PC, GPS, laptops and the likes, are commercialized and have become indispensable.

Although the functions of the consuming electronic products become more and more powerful, they are only limited in certain or some optimum applications. For example, regarding to the mobile phone and tablet PC, although their functions become similar, such as accessing internet, playing games, taking photos/videos, or displaying videos/movies, it is preferred to use the mobile phone to make a phone call, take photos, or record, and to use the tablet PC with larger screen to watch movies or browse webpage. Thus, many users may own these two individually operated electronic products at the same time. However, there is no such a portable electronic system that can integrate these two individual electronic products and interconnect them.

### SUMMARY OF THE INVENTION

The present disclosure provides a portable electronic system that can integrate two electronic devices and interconnect them to achieve their interactions, so that the user can easily enjoy the functions and services of two electronic devices. When a smaller electronic device needs a larger screen, it can be achieved by installing the smaller electronic device into another electronic device with larger screen, thereby increasing the convenience. In addition, when the small electronic device is not in use, it can be received in another electronic device for easy carry.

The present disclosure discloses a portable electronic system including a first electronic device, a carrying element and a second electronic device. The first electronic device has a casing. The casing has an accommodating portion located at one side of the casing. The carrying element is connected with the casing and capable of relatively moving between a first position and a second position of the casing. The second electronic device is disposed at the carrying element and coupled to the first electronic device. When the carrying element is located at the first position, the second electronic device is received within the accommodating portion by the carrying element. When the carrying element is located at the second position, the second electronic device is departed from the accommodating portion by the carrying element.

In one embodiment, the first electronic device comprises a tablet PC or a laptop.

In one embodiment, the second electronic device comprises a mobile phone, a PDA, a GPS, a digital camera, or a multimedia player.

In one embodiment, the accommodating portion is located at the back of the first electronic device.

In one embodiment, when the carrying element is located at the first position, a display surface of the first electronic device and a display surface of the second electronic device face toward the same direction.

In one embodiment, when the carrying element is located at the second position, a display surface of the first electronic device and a display surface of the second electronic device face toward the same direction.

In one embodiment, the portable electronic system further comprises a link unit disposed at the casing. The carrying element is relatively moving between the first position and the second position of the casing through the link unit.

In one embodiment, the link unit comprises at least a sliding rail disposed at the casing, the carrying element comprises a sliding groove corresponding to the sliding rail, and the carrying element is relatively moving between the first position and the second position of the casing through the sliding rail and the sliding groove.

In one embodiment, the link unit comprises at least a sliding groove disposed at the casing, the carrying element comprises a sliding rail corresponding to the sliding groove, and the carrying element is relatively moving between the first position and the second position of the casing through the sliding rail and the sliding groove.

In one embodiment, the link unit comprises at least a pivot shaft portion, the carrying element comprises a pivot connecting portion corresponding to the pivot shaft portion, and the carrying element is relatively rotating with respect to the casing through the pivot shaft portion and the pivot connecting portion.

In one embodiment, the link unit comprises at least a pivot connecting portion, the carrying element comprises a pivot shaft portion corresponding to the pivot connecting portion, and the carrying element is relatively rotating with respect to the casing through the pivot shaft portion and the pivot connecting portion.

In one embodiment, each of the first electronic device and the second electronic device has an individual operation system.

In one embodiment, the portable electronic system further comprises a transmission line for electrically connecting the first and second electronic devices. Herein, one end of the transmission line is connected with the first electronic device, and the other end thereof is connected with the second electronic device.

In one embodiment, the first electronic device and the second electronic device are coupled by r wireless transmission.

These and other features, aspects and advantages of the present invention will become better understood with regard to the following description, appended claims, and accompanying drawings.

### BRIEF DESCRIPTION OF THE DRAWINGS

FIG. 1A is a perspective front view of a portable electronic system according to a preferred embodiment of the disclosure;

FIGS. 1B and 1C are perspective rear views of the portable electronic system according to the preferred embodiment of the disclosure;

FIGS. 2A and 2B are perspective rear views of a portable electronic system of another aspect of the disclosure;

FIGS. 3A to 3C are perspective views of a portable electronic system of another aspect of the disclosure; and

FIG. 4 is a perspective rear view of a portable electronic system of another aspect of the disclosure.

### DETAILED DESCRIPTION OF THE INVENTION

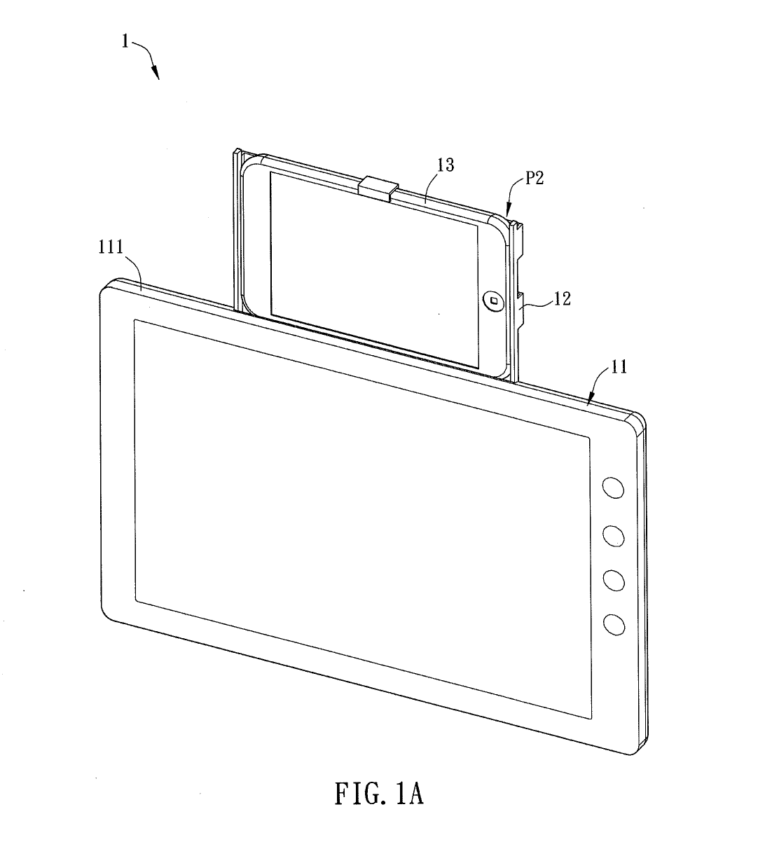

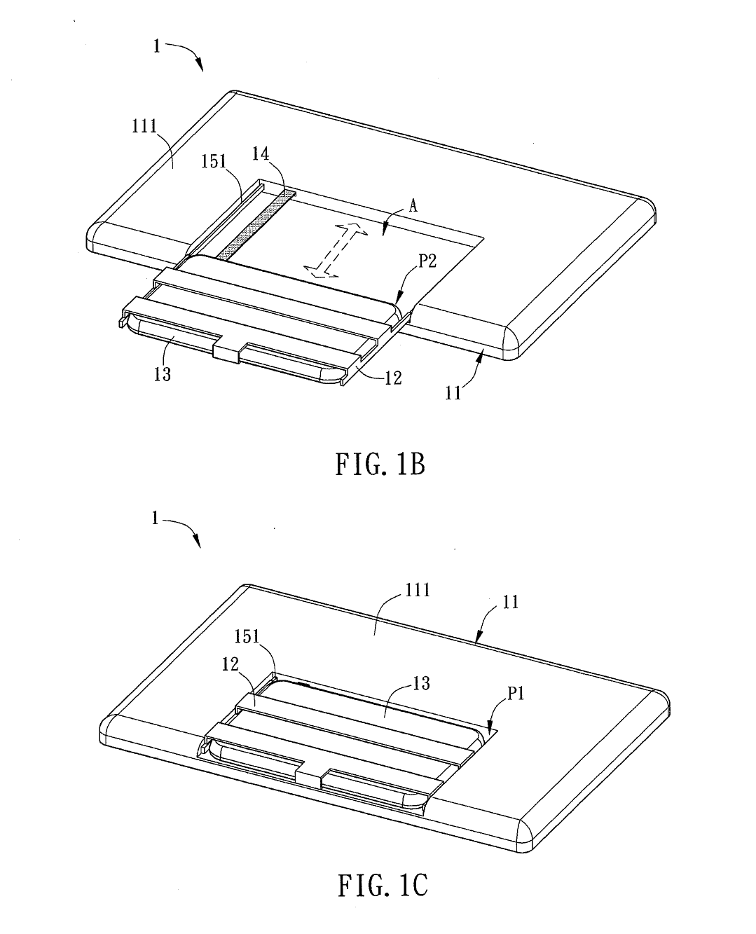

FIG. 1A is a perspective front view of a portable electronic system 1 according to a preferred embodiment of the disclosure, and FIGS. 1B and 1C are perspective rear views of the portable electronic system 1.

Referring to FIGS. 1A to 1C, the portable electronic system 1 includes a first electronic device 11, a carrying element 12 and a second electronic device 13. In the embodiment, the first electronic device 11 and the second electronic device 13 both have the touch control function, and each of them has an individual operation system.

The first electronic device 11 is, for example, a tablet PC or a laptop, and the second electronic device 13 is, for example, a smart phone, a PDA, a GPS, a digital camera, or a multimedia player (e.g. a MP3 or MP4 player).

In this embodiment, the first electronic device 11 is a tablet PC, and the second electronic device 13 is a smart phone. In addition, the carrying element 12 is a bracket (a bracket tray), a supporting frame (a supporting tray), or a carrying frame (a carrying tray). Herein, the carrying element 12 is a bracket, and the second electronic device 13 can be hooked and rested on the bracket.

The first electronic device 11 has a casing 111. As shown in FIG. 1B, the casing 111 has an accommodating portion A located at one side of the casing 111. In this embodiment, the front surface of the first electronic device 11 is a display surface, and the accommodating portion A is located at the long side of the rear surface of the casing 111 of the first electronic device 11.

With reference to FIGS. 1B and 1C, the carrying element 12 is connected with the casing 111 and capable of relatively moving between a first position P1 and a second position P2 of the casing 111. In other words, the carrying element 12 can be drawn out of the casing 111 or moved back into the casing 111, thereby relatively moving between the first position P1 and the second position P2 of the casing 111. As shown in FIG. 1C, when the carrying element 12 is located at the first position P1, it is completely received within the accommodating portion A. As shown in FIG. 1B, when the carrying element 12 is located at the second position P2, it is completely departed from the accommodating portion A.

The second electronic device 13 is disposed at the carrying element 12 and coupled to the first electronic device 11. The second electronic device 13 can be coupled to the first electronic device 11 by wired or wireless approach. In this embodiment, as shown in FIG. 1B, the portable electronic system 1 further comprises a transmission line 14. Herein, one end of the transmission line 14 is connected with the first electronic device 11, and the other end thereof is connected with the second electronic device 13. Thus, no matter the carrying element 12 is located at the first position P1 or the second position P2, the first electronic device 11 can successfully electrically connected with the second electronic device 13 through the transmission line 14, and the first electronic device 11 and the second electronic device 13 can transmit data to each other. In practice, the transmission line 14 can be hidden inside the machine body so that it will not affect the operation and appearance.

In some embodiments, the first electronic device 11 and the second electronic device 13 may also be coupled through a wireless transmission, which is, for example but not limited to, Bluetooth or wireless LAN. Besides, it is also possible to separate the transmission line 14 from the first electronic device 11 or the second electronic device 13, so that the user can separately operate the first electronic device 11 or the second electronic device 13.

As shown in FIG. 1C, when the carrying element 12 is located at the first position P1 (receiving position), the second electronic device 13 is received within the accommodating portion A by the carrying element 12, and a display surface of the first electronic device 11 and a display surface of the second electronic device 13 substantially face toward the same direction. Thus, the first electronic device 11 can be operated, the second electronic device 13, which is received, can not be directly operated. However, in one embodiment, the first electronic device can be operated to execute the corresponding instruction even when the second electronic device is in a receiving position. In another embodiment, the first electronic device 11 and the second electronic device 13 may face toward opposite directions.

Otherwise, as shown in FIGS. 1A and 1B, when the carrying element 12 is located at the second position P2 (operating position), the second electronic device 13 is departed from the accommodating portion A by the carrying element 12, and a display surface of the first electronic device 11 and a display surface of the second electronic device 13 face toward the same direction. Thus, the first electronic device 11 and the second electronic device 13 can be disposed to face toward the user, and be operated by the user with desired interactions.

The “interaction” between two electronic devices may include various contents based on the requirements. The “interaction” may include the support of power source or the data or operation interaction therebetween. For example, when the user plays a game on the tablet PC (the first electronic device 11), and the mobile phone (the second electronic device 13) receives an incoming call, the tablet PC will automatically pause the game and display a touch control option of “Continue” or “Quit”. Then, the user decides to continue or quit the game, or answers the incoming call in advance and selects “Continue” to continuously play the game (answering the incoming call does not affect the progress of the game) or selects “Quit” to quit the game.

Besides, the user may use one hand to operate some functions of the mobile phone, and the other hand to operate the tablet PC. In addition, the user may drag an object from the display screen of the mobile phone to the display screen of the tablet PC, or from the display screen of the tablet PC to the display screen of the mobile phone. Herein, the destination screen of the dragged object may show any corresponding display so as to provide the desired interaction with the user.

Moreover, the portable electronic system 1 further includes a link unit disposed at the casing 111, and the carrying element 12 is relatively moving between the first position P1 and the second position P2 of the casing 111 through the link unit. Referring to FIG. 1B again, the link unit may comprise at least a sliding rail 151 disposed on the casing 111 and located at one side of the accommodating portion A. The carrying element 12 comprises two sliding grooves corresponding to the sliding rails 151, wherein the sliding grooves (not shown) are disposed at two sides of the carrying element 12. Herein, the link unit includes two sliding rails 151 corresponding to two sliding grooves (although FIG. 1B only shows one sliding rail 151). Thus, the carrying element 12 can be relatively moving between the first position P1 and the second position P2 of the casing 111 through the sliding rails 151 and the sliding grooves. In this embodiment, the sliding rails 151 are integrally formed with the casing 111, or are separated components fixed on the casing 111. Of course, in another aspect, the sliding grooves are disposed on the casing 111, and the carrying element 12 is configured with the corresponding sliding grooves.

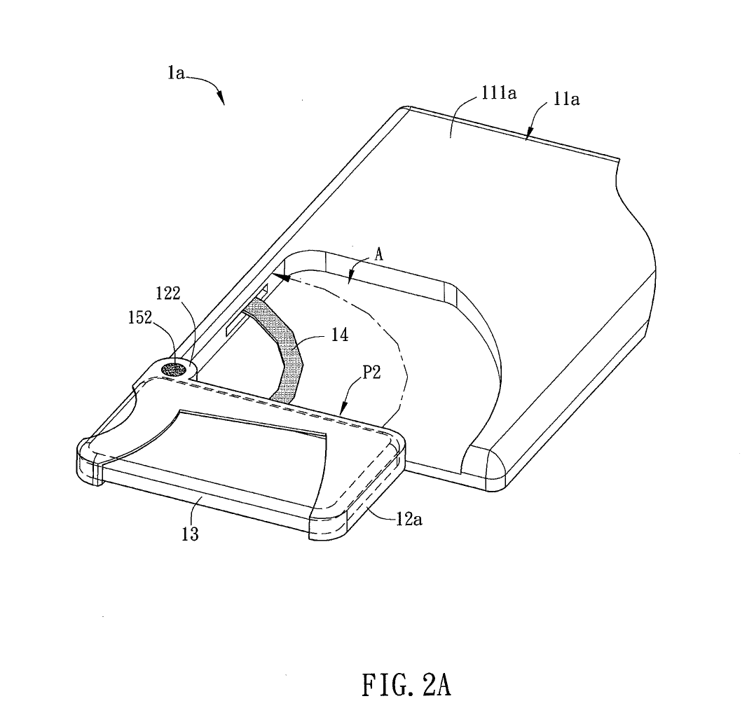

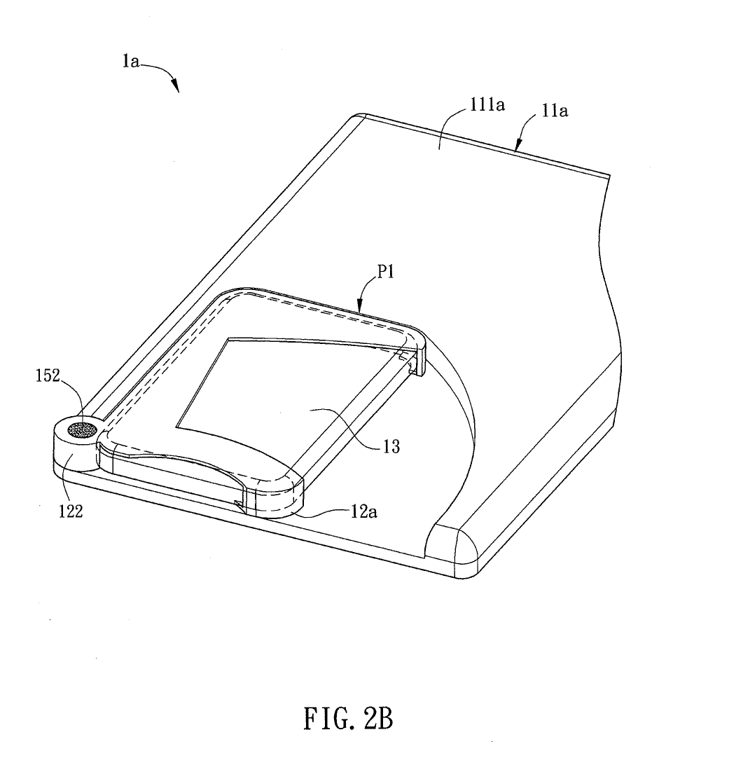

FIGS. 2A and 2B are perspective rear views of a portable electronic system 1a of another aspect of the disclosure.

Different from the portable electronic system 1, the accommodating portion A of the portable electronic system 1a is disposed at the short side of the rear surface of the casing 111a of the first electronic device 11a. In addition, the linking mechanism of the portable electronic system 1a includes at least a pivot shaft portion 152 disposed at the casing 111a, and the carrying element 12a includes a pivot connecting portion 122 corresponding to the pivot shaft portion 152. Wherein, the carrying element 12a is relatively moving between the first position P1 and the second position P of the casing 111a through the pivot shaft portion 152 and the pivot connecting portion 122. In more specific, the pivot shaft portion 152 is located at one side of the casing 111a and is integrally formed with the casing 111a, while the pivot connecting portion 122 is disposed at one side of the carrying element 12a and is integrally formed with the carrying element 12a. Thus, the carrying element 12a can be rotated in horizontal with respect to the casing 111a through the pivot shaft portion 152 and the pivot connecting portion 122, thereby moving between the first position P1 and the second position P of the casing 111a.

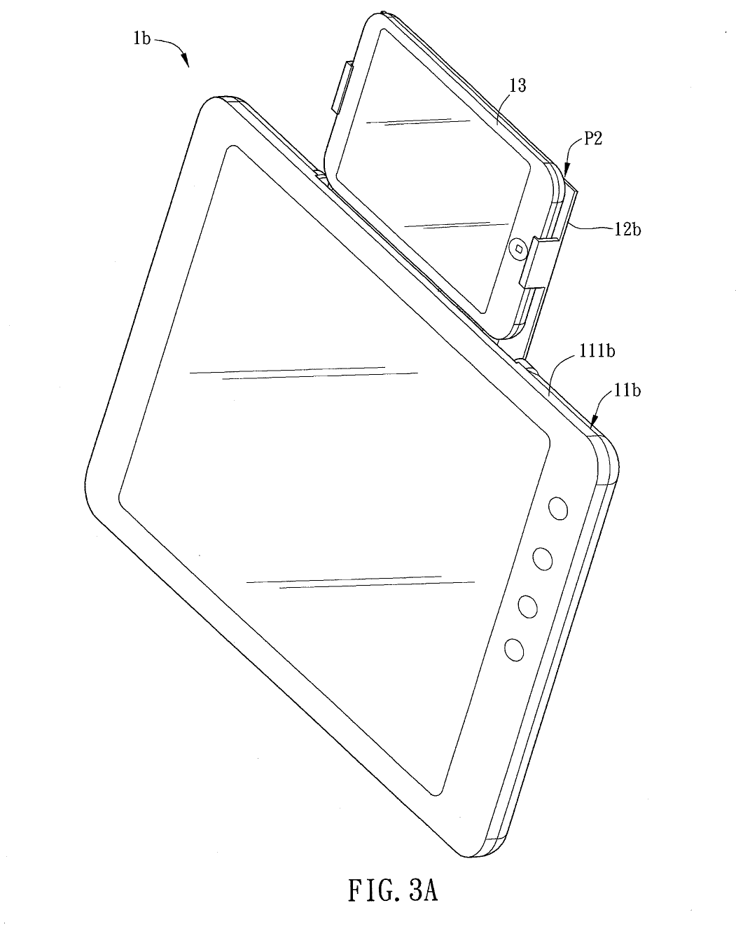

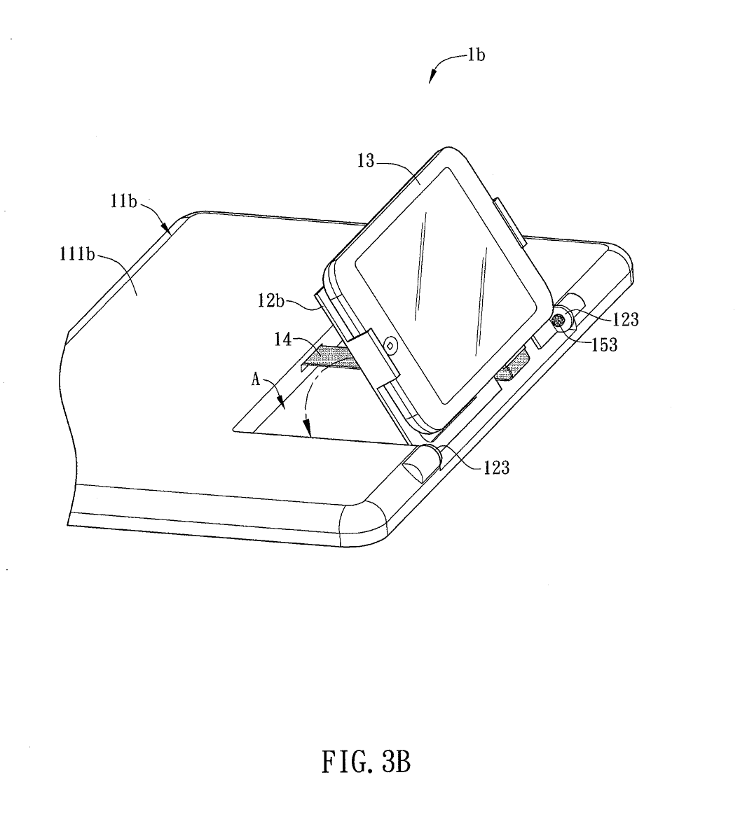

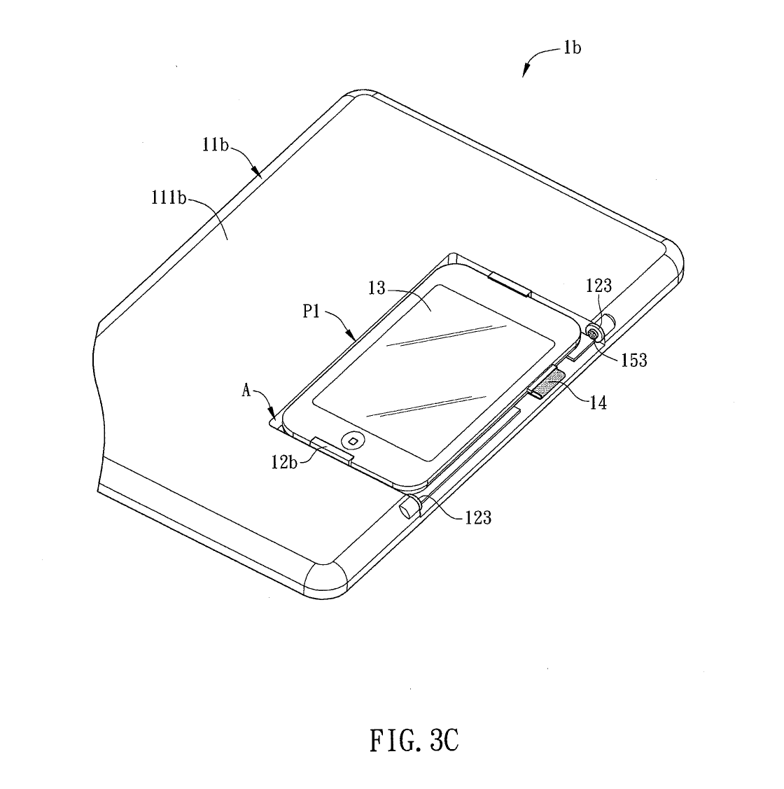

FIGS. 3A to 3C are perspective views of a portable electronic system 1b of another aspect of the disclosure.

Different from the portable electronic system 1, the linking mechanism of the portable electronic system 1b includes two pivot shaft portions 153 disposed at the casing 111b and disposed at two sides of the accommodating portion A, and the carrying element 12b includes two pivot connecting portions 123 corresponding to the pivot shaft portion 153. Wherein, the carrying element 12b is relatively moving between the first position P1 and the second position P of the casing 111b through the pivot shaft portions 153 and the pivot connecting portions 123. The carrying element 12b is capable of rotating for 180 degrees. In this case, the pivot shaft portions 153 are integrally formed with the casing 111b, while the pivot connecting portions 123 are integrally formed with the carrying element 12b. This configuration can increase the structural strength. In addition, as shown in FIG. 3C, when the carrying element 12b is located at the first position P1, the display surface of the first electronic 11b and the display surface of the second electronic device 13 face toward opposite directions (upwards and downwards respectively).

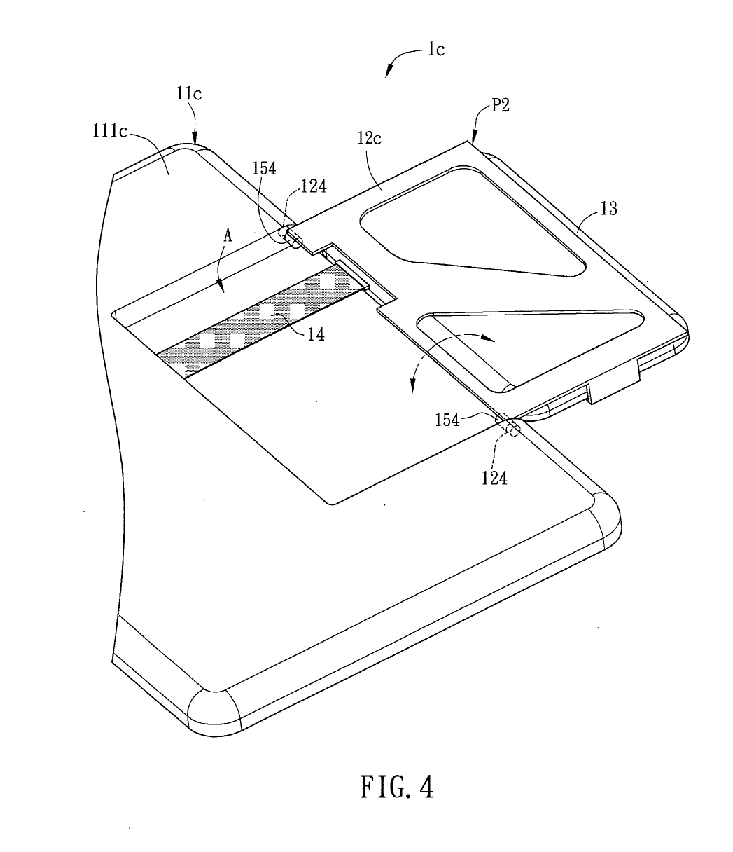

FIG. 4 is a perspective rear view of a portable electronic system of another aspect of the disclosure.

Different from the portable electronic system 1b of FIGS. 3A to 3C, two pivot shaft portions 154 of the portable electronic system 1c are disposed at two sides of the carrying element 1c, and two pivot connecting portions 124 are disposed at two sides of the casing 111c. Similarly, the carrying element 12c is capable of rotating for 180 degrees, thereby moving between the first position P1 and the second position P2 of the casing 111c (FIG. 4 only shows the position P2).

The other technical features of the portable electronic systems 1a, 1b and 1c can be referred to the portable electronic system 1, so the detailed descriptions thereof are omitted.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A portable electronic system, comprising:
a first electronic device having a casing, wherein the casing has an accommodating portion located at one side of the casing;
a carrying element connected with the casing and capable of relatively moving between a first position and a second position of the casing; and
a second electronic device disposed at the carrying element and coupled to the first electronic device;
wherein, when the carrying element is located at the first position, the second electronic device is received within the accommodating portion by the carrying element, and when the carrying element is located at the second position, the second electronic device is departed from the accommodating portion by the carrying element.

2. The portable electronic system of claim 1, further comprising:
a link unit disposed at the casing, wherein the carrying element is relatively moving between the first position and the second position of the casing through the link unit.

3. The portable electronic system of claim 2, wherein the link unit comprises at least a sliding rail or a sliding groove, and the carrying element is relatively moving between the first position and the second position of the casing through the sliding rail or the sliding groove.

4. The portable electronic system of claim 2, wherein the link unit comprises at least a pivot shaft portion and a pivot connecting portion, and the carrying element is relatively rotating with respect to the casing through the pivot shaft portion and the pivot connecting portion.

5. The portable electronic system of claim 1, wherein each of the first electronic device and the second electronic device has an individual operation system.

6. The portable electronic system of claim 1, wherein when the carrying element is located at the first position, a display surface of the first electronic device and a display surface of the second electronic device face toward the same direction.

7. The portable electronic system of claim 1, wherein when the carrying element is located at the second position, a display surface of the first electronic device and a display surface of the second electronic device face toward the same direction.

8. The portable electronic system of claim 1, wherein the first electronic device and the second electronic device are coupled by wired or wireless.
